(19) United States
(12) Patent Application Publication
(10) Pub. No.: US 2004/0008485 A1
(43) Pub. Date: Jan. 15, 2004

(54) Electronic apparatus

(76) Inventors: Takashi Naganawa, Chiyoda (JP); Shigeo Ohashi, Tsuchiura (JP); Yoshihiro Kondo, Tsuchiura (JP); Rintaro Minamitani, Tsukuba (JP); Tsuyoshi Nakagawa, Hadano (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/615,831

(22) Filed: Jul. 10, 2003

(30) Foreign Application Priority Data
Jul. 15, 2002 (JP) 2002-204978

(51) Int. Cl. G06F 1/20; H05K 7/20

(52) U.S. Cl. 361/687; 165/80.3; 62/259.2; 174/15.2; 361/700

(57) ABSTRACT

There is provided an electronic apparatus having a liquid-cooled structure appropriate to downsized and thin models and a long useful life. The structure has a necessary and sufficient circulating fluid amount in correspondence with increase in heat generation amount of heat generating device accompanying improvement in processing performance of electronic device. An incoming radiational jacket is thermally connected to a heat generating device, and thermally connected to a tank, first and second pipes and a radiation panel provided on the rear surface of display. Coolant liquid is circulated between the incoming radiational jacket and a third pipe by a pump. Further, a metal radiation panel is covered with a resin display cover.

### FIELD OF THE INVENTION

The present invention relates to an electronic apparatus loaded with a cooling device using liquid as radiation medium.

### BACKGROUND OF THE INVENTION

In recent years, with increase in requirement for high speed processing and large capacity of electronic apparatus, the value of heat generation by semiconductor device increases. As means for handling the increase in the value of heat generation, cooling means disclosed in e.g. Japanese Patent Laid-open No. H6(1994)-266474 and H7(1995)-142886 are known.

An electronic apparatus disclosed in Japanese Patent Laid-open No. H6(1994)-266474 has a main body case accommodating a wiring board on which a heat generating device is mounted, and a display device case, having a display panel, rotatably attached to the main body case by a hinge. An incoming radiational jacket is attached to the heat generating device, and liquid heated by heat absorption by the incoming radiational jacket is radiated from a radiation pipe provided in the display device case. The liquid circulates by a liquid driving mechanism attached in the middle of piping route connecting the incoming radiational jacket with the radiation pipe. The pipe connecting the hinge portion is a flexible tube.

Further, according to Japanese Patent Laid-open No. H7(1995)-142886, the case disclosed in Japanese Patent Laid-open No. H6(1994)-266474 is made of metal for improvement in heat radiation effect.

Since these conventional techniques provide higher cooling capability in comparison with forced cooling by fan, and further provide low-noise cooling, they can be effectively used in cooling of electronic apparatus.

In electronic apparatuses represented by a portable personal computer or the like, the value of heat generation by device is remarkably increasing in accordance with improvement in performance. On the other hand, reduction of size and thickness of case is desired for portability.

The above conventional techniques are effective in cooling of electronic apparatus, however, for electronic apparatuses to be further reduced in size and thickness in the future, further reliable cooling is required.

### SUMMARY OF THE INVENTION

The present invention has its object to provide an electronic apparatus using highly-reliable liquid cooling.

The foregoing object is attained by providing an electronic apparatus having a first case to which a heat generating device is attached and a second case which is rotatably supported on the first case with plural hinges and which has a display device, comprising: an incoming radiational jacket connected to the heat generating device; a radiation pipe attached in the second case; a radiation plate attached to the radiation pipe; a tank attached to the radiation plate; and liquid driving means, attached in the first case, for transferring liquid in the tank to the incoming radiational jacket, wherein the plural hinges include a first hinge through which a tube for transferring the liquid is passed, and a second hinge through which an electric wire from the display device is passed.

The foregoing object is also attained by arranging in the above electronic apparatus such that a distance covered by the liquid from the incoming radiational jacket to the tank is longer than a distance covered by the liquid from the tank through the liquid driving means to the incoming radiational jacket.

The foregoing object is also attained by arranging in the above electronic apparatus such that a resin display case covering the radiation plate forms a rear surface of the second case.

The foregoing object is also attained by arranging in the above electronic apparatus such that the tank is accommodated in the first case, and wherein the radiation pipe in the second case has a flat shape.

Further, the foregoing object is also attained by arranging in the above electronic apparatus such that the depth of the display case corresponds to the thickness of the tank.

Further, the foregoing object is also attained by arranging in the above electronic apparatus such that the tank is placed in a position closest to the first hinge through which a tube for transferring the liquid is passed.

Further, the foregoing object is also attained by arranging in the above electronic apparatus such that the tank is covered with the radiation plate, and the radiation plate is covered with the display case.

### BRIEF DESCRIPTION OF THE DRAWINGS

FIG. 1 is a perspective view of electronic apparatus according to a first embodiment;

FIG. 2 is a perspective view showing parts of liquid coolant circulation route according to the first embodiment;

FIG. 3 is a rear view of the electronic apparatus according to the first embodiment;

FIG. 4 is a side view of the electronic apparatus according to the first embodiment;

FIG. 5 is a perspective view of the electronic apparatus according to the first embodiment viewed from the rear surface side;

FIG. 6 is a rear view of the electronic apparatus according to a second embodiment;

FIG. 7 is a perspective view of the electronic apparatus according to the second embodiment viewed from the rear surface side;

FIG. 8 is a perspective view of the electronic apparatus according to a third embodiment; and

FIG. 9 is a perspective view of the electronic apparatus according to a fourth embodiment.

### DETAILED DESCRIPTION OF THE PREFERRED EMBODIMENTS

The technique of cooling a semiconductor device in an electronic apparatus by liquid is conventionally known and is performed in a large computer used in banks and companies.

In the cooling device of large computer, a large amount of liquid is circulated to the semiconductor device by a pump, and the heated liquid is forcibly radiated by heat absorption from the semiconductor device by using a specialized radiation device installed in e.g. an outdoor position.

The most important matter upon loading of the cooling device using liquid on an electronic apparatus (heat-generating devices such as a television set, a liquid crystal projector, and an electronic cooking appliance as well as a personal computer), is safety.

Since a set of pump, incoming radiational jacket, flexible tube and radiation jacket are installed in the electronic apparatus despite sense of resistance about entrance of water in the electronic apparatus, at least the tube and electric wiring must be arranged away from each other as much as possible.

Accordingly, the result of various studies on the safety in the case of installation of cooling device using liquid in the electronic apparatus will be described in the following embodiments according to the present invention.

(First Embodiment)

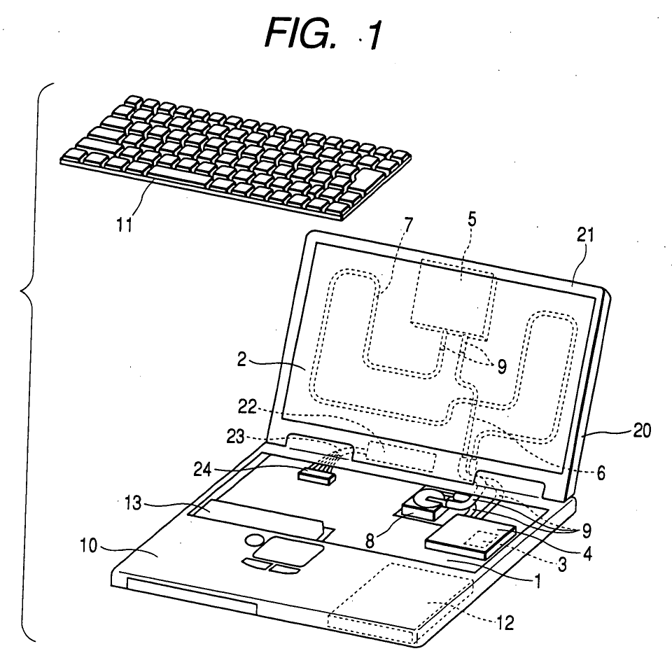

FIG. 1 is a perspective view of electronic apparatus according to a first embodiment of the present invention.

In FIG. 1, the electronic apparatus has a main body case 10 and a display case 20 with a display 2. A keyboard 11, a main wiring board 1 on which plural devices are mounted, a hard disk drive 12, an auxiliary storage device (e.g. a floppy disk drive, a CD drive or the like) 13 and the like are provided in the main body case 10. A device having an especially large heat release value (hereinafter, referred to as CPU) such as a CPU (central processing unit) 3, a connector 24 for electric signal to the display 2 and the like are mounted on the main wiring board 1. Note that for the sake of explanation, the figure shows a status where the keyboard 11 is removed from the apparatus.

The display 2 is accommodated in the display case 20 with a display frame 21. A display wiring board 22 is provided below the display 2, and the display wiring board 22 is connected with the connector 24 on the main wiring board 1 via an electric wire 23 for electric signal transmission.

An incoming radiational jacket 4 is attached to the CPU 3. The CPU 3 and the incoming radiational jacket 4 are connected with each other via a flexible thermal conduction material (e.g. Si rubber mixed with thermal conduction filler such as aluminum oxide (not shown)). Further, the display 2 is supported by the display frame 21 and the display case 20. A tank 5, a tank exit-side pipe 6 and a tank entrance-side pipe 7 are provided between the display 2 and the display case 20. The tank 5 is filled with a liquid coolant (water, antifreeze liquid or the like).

Further, a pump 8 as liquid transfer means is provided in the main body case 10. The tank 5, the tank exit-side pipe 6, the pump 8, the incoming radiational jacket 4 and the tank entrance-side pipe 7 are interconnected by flexible tubes 9, thereby forming a closed coolant circuit where the liquid coolant is circulated by operation of the pump 8. Heat generated by the CPU 3 is conducted to the liquid coolant passing through the incoming radiational jacket 4, and radiated to the ambient air via a radiation panel 25 to be described later and the surface of the display case 20 while the liquid coolant passes through the tank entrance-side pipe 7, the tank 5 and the tank exit-side pipe 6 provided on the rear surface of the display 2. The temperate-reduced liquid coolant is transferred to the incoming radiational jacket 4 via the pump 8.

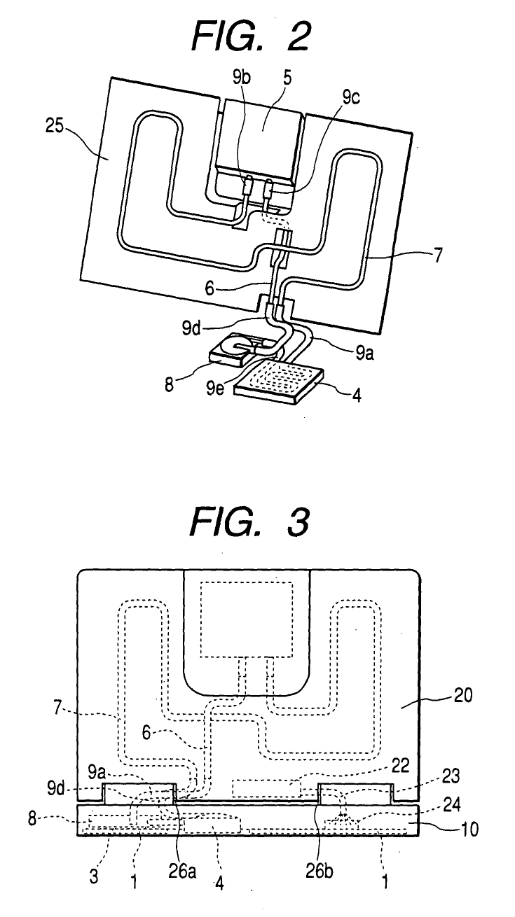

FIG. 2 is a perspective view of parts of liquid channel of the first embodiment through which the liquid coolant is circulated.

In FIG. 2, by operating the pump 8, the liquid coolant is circulated through the incoming radiational jacket 4, the tank entrance-side pipe 7, the tank 5, the tank exit-side pipe 6 and the pump 8.

In the present embodiment, the incoming radiational jacket 4 is made of light-weight aluminum alloy having high thermal conductivity. The tank entrance-side pipe 7 and the tank exit-side pipe 6 are made of stainless steel having high corrosion resistance and high thermal conductivity. The tank 5 is made of light-weight and high-strength resin with low water permeability (SPS: syndiotac polystyrene). The outer case of the pump 8 is made of resin with high mechanical strength (PPS: polyphenylene sulfide resin+40% glass fiber) which can be easily molded to a complicated shape. The flexible tubes 9a to 9e connecting the respective parts are made of: butyl rubber.

As represented by a vehicle tire tube, butyl rubber having high thermal resistance, high impact resistance and high transmittance resistance, can be effectively used in cooling of electronic apparatus in which a display case is always opened/closed and liquid flows as in the case of the present embodiment.

Further, the tank entrance-side pipe 7 and the tank exit-side pipe 6 are provided on the radiation panel 25 of aluminum, and as they are thermally connected, the area of radiation is enlarged.

Further, the tank entrance-side pipe 7 is longer than the tank exit-side pipe 6 such that the pipe 7 forms a liquid channel for the liquid coolant radiated to have a lower temperature to enter the tank 5.

Further, the surface of the tank 5 is coated with a metal thin film for radiation from the metal film, and further, the metal film reduces permeation of liquid coolant from the resin tank 5.

Note that the tank 5 is made of resin since the resin is light-weight material and it can be comparatively easily molded.

Note that in the present embodiment, the tank 5 is made of resin and the surface thereof is coated with a metal thin film, however, it may be arranged such that the tank itself is made of metal and the permeation of liquid coolant is prevented. In a case where a metal tank is manufactured, a flat metal plate is caulked with the edge of metal cup formed by drawing (the formation process is approximately the same as manufacturing of e.g. elliptic can).

FIG. 3 is a rear view of the electronic apparatus (in a status where the display case 20 is opened) according to the first embodiment.

In FIG. 3, hinges 26a and 26b are connection portions between the main body case 10 and the display case 20. The display case 20 can open/close the upper surface of the main body case 10 by the hinges 26a and 26b.

The flexible tube 9a connecting the tank entrance-side pipe 7 with the incoming radiational jacket 4, and the flexible tube 9d connecting the pump 8 with the tank exit-side pipe 6, are passed through the hinge 26a. The pump 8 on the main wiring board 1 is provided on the hinge 26a side. The arrangement is made in consideration of safety by setting the water piping in the main body case 10 as short as possible.

The electric wire 23 electrically connecting the display wiring board 22 with the connector 24 on the main wiring board 1 is passed through the hinge 26b.

As described above, the hinges are independently provided in correspondence with type of piping or wiring. That is, the hinge 26a is provided for the circulation route of the liquid coolant, and the hinge 26b, for the electric signal. By discriminating the region of electric system through which the electric wiring is passed, from the region of liquid through which the liquid flows, by utilizing 2 hinges, factors of electric troubles are eliminated as much as possible.

Note that the design is made in consideration of safety such that at least in a status where the electronic apparatus is used, the flexible tubes are not positioned on the wiring board.

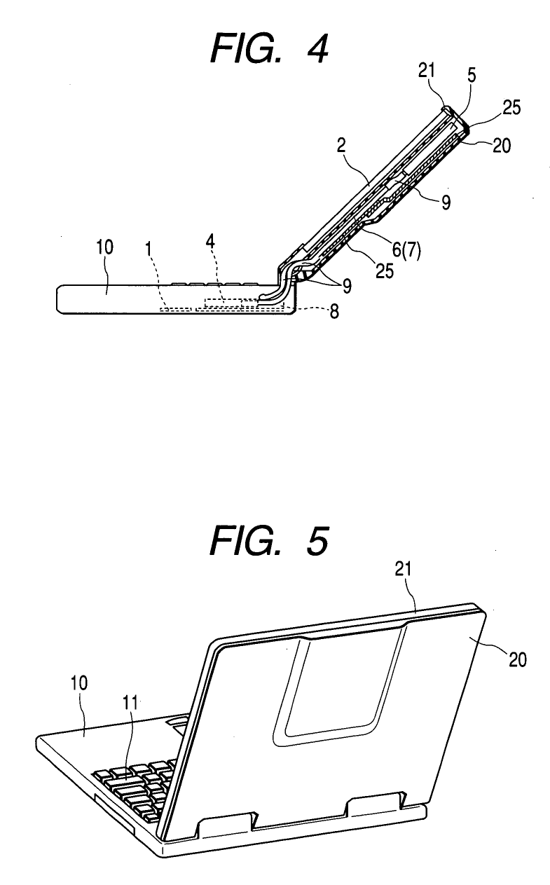

FIG. 4 is a side view of the electronic apparatus according to the first embodiment in which the display case 20 is opened.

In FIG. 4, the tank exit-side pipe 6 and the tank entrance-side pipe 7 are provided on the radiation panel 25, and are connected with the incoming radiational jacket 4 and the pump 8 in the main body case 10 and the tank 5 on the display case 20 side via the flexible tubes 9. The display 2 is provided in the display frame 21, and the rear surface of the display 2 is covered with the display frame 21.

Further, the display case 20 is attached to the display frame 21, thereby the tank exit-side pipe 6, the tank entrance-side pipe 7, the tank 5 and the radiation panel 25 are provided between the display frame 21 and the display case 20. In the upper part of the display 2, the display 2, the display frame 21, the tank 5, the radiation panel 25 and the display case 20 are provided from the top. The tank 5 is covered with a part of the radiation panel 25, and the radiation panel 25 is covered with the display case 20.

As the tank 5 is protected by the radiation panel 25, even if a shock is applied from the display case 20 side, the tank 5 is protected by the radiation panel 25.

FIG. 5 is a perspective view of the electronic apparatus according to the first embodiment in an opened status viewed from the rear surface side.

In FIG. 5, the main body case 10, the keyboard 11, the display case 20 and the display frame 21 are made of resin.

Especially, as the display case 20 cover the tank 5 and the radiation panel 25 they become hot when the CPU 3 generates heat, the display case 20 plays an important role as a protector for an operator from burn injury.

(Second Embodiment)

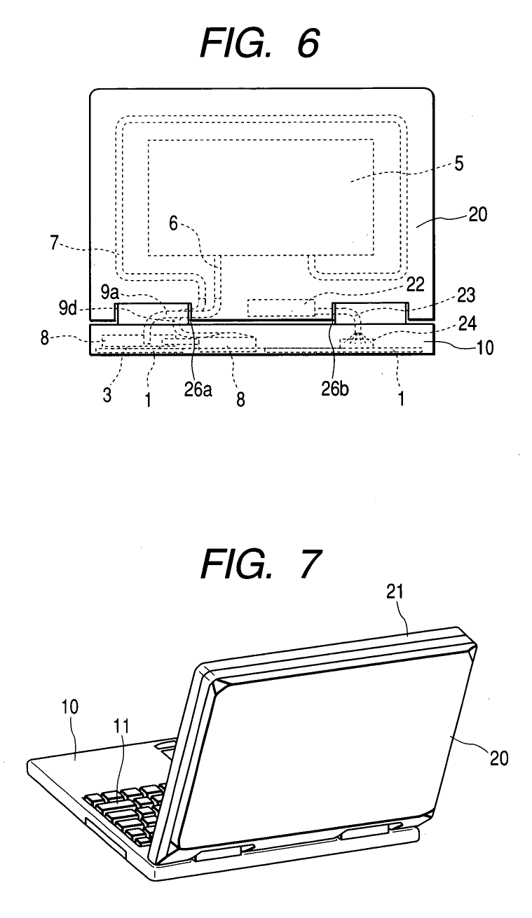

FIG. 6 is a rear view of the electronic apparatus (in a status where the display case 20 is opened) according to a second embodiment.

In FIG. 6, the basic structure of the embodiment is approximately the same as that described in FIGS. 1 to 5 except that the tank 5 is thinned so as to enlarge the area.

The tank entrance-side pipe 7 is longer than the tank exit-side pipe 6 such that the pipe 7 forms a liquid channel for the liquid coolant radiated via the radiation panel 25 to have a lower temperature to enter the tank 5. Further, also in the present embodiment, the hinge 26a is provided for the circulation route of the liquid coolant, and the hinge 26b, for the electric signal.

FIG. 7 is a perspective view of the electronic apparatus according to the second embodiment described in FIG. 6 viewed from the rear surface side.

In FIG. 7, as the tank 5 is thinned and the area thereof is enlarged, a bulge at the central portion of the display case 20 as shown in FIG. 5 is eliminated, thus an excellent design can be attained.

Further, since the effect if radiation from the tank 5 itself is increased by increment of surface area of the tank 5, the number of bends of the tank entrance-side pipe 7 can be reduced and the pipe 7 itself can be shortened. Thus the flow rate of the liquid can be increased. As a result, the cooling efficiency can be improved.

(Third Embodiment)

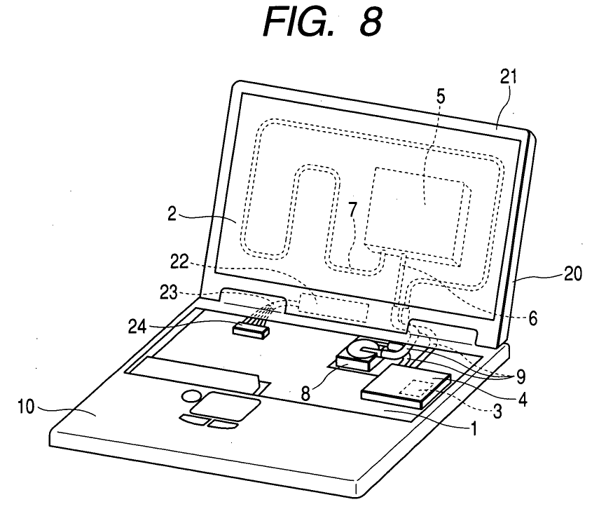

FIG. 8 is a perspective view of the electronic apparatus according to a third embodiment.

In FIG. 8, the basic structure of the embodiment is approximately the same as that described in FIGS. 1 to 5 except that the position of the tank 5 provided between the display 2 and the display case 20 is shifted.

As the position of the tank 5, a position closest to the hinge through which the liquid pipe is passed is effective. By this arrangement, the tank exit-side pipe 6 can be straight and the length of the pipe can be shortest. As a result, as it is understood from comparison with FIG. 1, the flow rate of the liquid is increased by the reduction of the number of bends of the tank entrance-side pipe 7, and the electric consumption amount of the pump can be reduced.

(Fourth Embodiment)

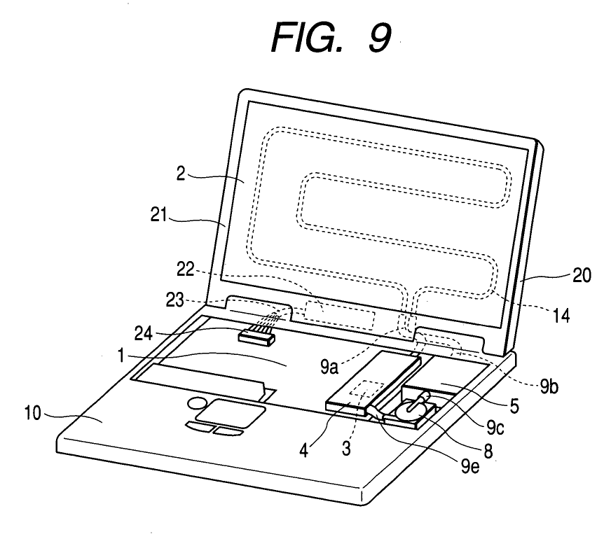

FIG. 9 is a perspective view of the electronic apparatus according to a fourth embodiment in which the tank 5 is provided in the main body case 10.

In FIG. 9, a pipe 14, made of metal, is sandwiched between the display 2 and the display case 20. The pipe 14 is connected to the incoming radiational jacket 4 in the main body case 10 via the flexible tube 9a, and further connected to the tank 5 via the flexible tube 9b. The pump 8 is connected to the incoming radiational jacket 4 via the flexible tube 9e, and further connected to the tank 5 via the flexible tube 9c.

By operating the pump 8, the liquid coolant is circulated through the incoming radiational jacket 4, the pipe 14, the tank 5 and the pump 8. The liquid channel is formed such that the liquid coolant is cooled while it flows through the pipe 14, and the liquid coolant at a lowered temperature enters the tank 5.

In this manner, even if the tank 5 is provided, not between the display 2 and the display case 20 but in the main body case 10, the CPU 3 can be sufficiently cooled.

Note that as the tank 5 is provided in the main body case 10, the display case 20 can be thinned. To further thin the display case 20, the pipe 14 on the display case 20 side can be a flat pipe having an elliptic cross section. In use of flat pipe, the display case 20 can be thinned, and further, as the area of contact with the radiation panel can be enlarged, the radiation efficiency can be increased.

The tank 5 and the pump 8 are connected with each other via the flexible tube 9c, however, the flexible tube 9c may be eliminated and covers of surfaces forming the tank 5 and the pump 8 may be integrated with each other.

As described above, as the hinge for the liquid coolant circulation route and the hinge for electric wire are separated, even if leakage of the liquid coolant occurs, electric troubles can be prevented.

Further, as the metal radiation panel is covered with the resin display case, the operator does not directly touch the high-temperature metal part. The apparatus is designed in consideration of safety from burn injury or the like.

According to the present invention, an electronic apparatus using highly-reliable liquid cooling can be provided.

What is claimed is:

1. An electronic apparatus having a first case to which a heat generating device is attached and a second case which is rotatably supported on the first case with plural hinges and which has a display device, comprising:
an incoming radiational jacket connected to the heat generating device;
a radiation pipe attached in the second case;
a radiation plate attached to the radiation pipe;
a tank attached to the radiation plate; and
liquid driving means, attached in the first case, for transferring liquid in the tank to the incoming radiational jacket,
wherein the plural hinges include a first hinge through which a tube for transferring the liquid is passed, and a second hinge through which an electric wire from the display device is passed.

2. The electronic apparatus according to claim 1, wherein a distance covered by the liquid from the incoming radiational jacket to the tank is longer than a distance covered by the liquid from the tank through the liquid driving means to the incoming radiational jacket.

3. The electronic apparatus according to claim 1, wherein a resin display case covering the radiation plate forms a rear surface of the second case.

4. The electronic apparatus according to claim 1, wherein the tank is accommodated in the first case, and wherein the radiation pipe in the second case has a flat shape.

5. The electronic apparatus according to claim 1, wherein the depth of the display case corresponds to the thickness of the tank.

6. The electronic apparatus according to claim 1, wherein the tank is placed in a position closest to the first hinge through which a tube for transferring the liquid is passed.

7. The electronic apparatus according to claims 1 and 3, wherein the tank is covered with the radiation plate, and the radiation plate is covered with the display case.
